(19) United States
(12) Patent Application Publication
(10) Pub. No.: US 2007/0030633 A1
(43) Pub. Date: Feb. 8, 2007

(54) Display device having mechanism for fixing protective screen

(75) Inventor: Yaw-Shing Tseng, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/500,530

(22) Filed: Aug. 8, 2006

(30) Foreign Application Priority Data
Aug. 8, 2005 (TW) 94126743

(51) Int. Cl. G06F 1/16; H05K 7/00; H05K 5/00

(52) U.S. Cl. 361/681; 361/679

(57) ABSTRACT

An exemplary display device (10) includes a display screen (11), a protective screen (19), and a housing (13) accommodating the display screen. The housing includes a mechanism for fixing the protective screen immediately in front of the display screen. The mechanism is configured as grooves (133) in a front portion of the housing, or blocks (433) integrally formed with the housing, which conveniently provides fixing of the protective screen in front of the display screen.

### FIELD OF THE INVENTION

The present invention relates to display devices, and especially to a display device having a mechanism for conveniently fixing a protective screen at a front thereof.

### BACKGROUND

During the operation of the monitor of a television set, a liquid crystal display, or certain other electronic display devices, unwanted incidental radiation is released from the display screen of the monitor. It may be appropriate or even required by applicable health regulations to have a protective screen fitted in front of the display screen. The protective screen functions as a filter for reducing radiation exposure. Various protective screens have been devised for reducing or eliminating the incidental radiation released by monitors, as well as for performing the function of enhancing the contrast or other characteristics of images provided by the display screen.

A typical protective screen includes a flat transparent plate held in a peripheral frame, and a hanging portion connected with or integrally formed with the frame. The hanging portion is mounted on a top part of a display device, so that the flat transparent plate is suspended immediately in front of a display screen of the display device. The frame and the hanging portion may be made of plastic or metallic material.

With this configuration, the frame of the protective screen is liable to interfere with the line of sight of a user viewing the display screen, particularly if the suspended flat transparent plate is displaced. Moreover, the protective screen including the frame and the hanging portion may be unduly expensive.

Accordingly, what is needed is a display device that can overcome the above-described deficiencies.

### SUMMARY

An exemplary display device includes a display screen, a protective screen, and a housing accommodating the display screen. The housing includes a mechanism for fixing the protective screen immediately in front of the display screen.

The mechanism is configured as grooves in a front portion of the housing, or blocks integrally formed with the housing, which conveniently provides fixing of the protective screen in front of the display screen.

Other advantages and novel features will become more apparent from the following detailed description of preferred embodiments when taken in conjunction with the accompanying drawings. In the drawings, all the views are schematic.

### BRIEF DESCRIPTION OF THE DRAWINGS

FIG. 1 is an exploded, isometric view of a display device having a protective screen according to a first embodiment of the present invention.

FIG. 2 is an assembled view of the display device of FIG. 1.

FIG. 3 is an exploded, isometric view of a display device having a protective screen according to a second embodiment of the present invention.

FIG. 4 is an exploded, isometric view of a display device having a protective screen according to a third embodiment of the present invention.

FIG. 5 is an exploded, isometric view of a display device having a protective screen according to a fourth embodiment of the present invention.

FIG. 6 is an assembled view of the display device of FIG. 5.

### DETAILED DESCRIPTION OF PREFERRED EMBODIMENTS

Reference will now be made to the drawings to describe the preferred embodiments in detail.

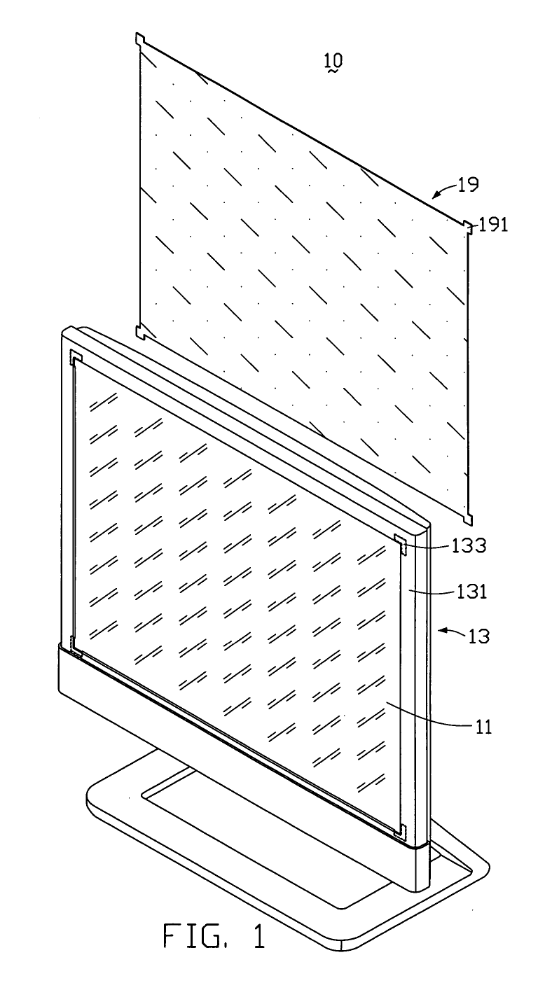

FIG. 1 is an exploded, isometric view of a display device having a protective screen according to a first embodiment of the present invention. The display device 10 includes a display screen 11 accommodated in a housing 13, and a protective screen 19. The protective screen 19 may be made of polycarbonate or a like material, and the housing 13 may be made of plastic material.

The housing 13 includes a front frame 131 that covers peripheral edge portions (not labeled) of the display screen 11, whereby the display screen 11 is held in the housing 13. A main central portion of the display screen 11 is not covered by the housing 13, and forms a viewing area (not labeled). The front frame 131 of the housing 13 includes four grooves 133 defined in four inner corner portions thereof respectively, adjacent to four corners of the viewing area respectively. The protective screen 19 has a size corresponding to that of the viewing area, and includes four protrusions 191 extending from four corners thereof respectively. A size of the protrusions 191 matches a size of the grooves 133.

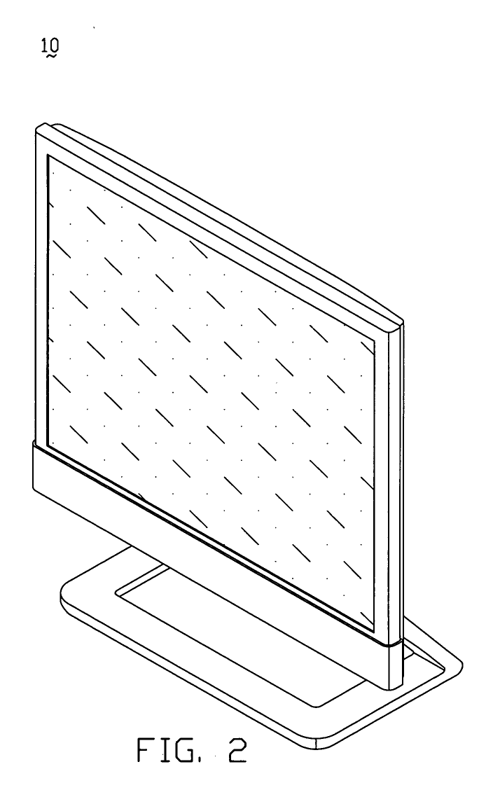

Referring to FIG. 2, in assembly, the protrusions 191 are fixed in the corresponding grooves 133 of the front frame 131, so as to fix the protective screen 19 immediately in front of the viewing area of the display screen 11.

The four grooves 133 of the front frame 131 can be considered cooperatively as part of a fixing mechanism, which conveniently provides fixing of the protective screen 19 in front of the display screen 11. Moreover, unlike in prior art, the protective screen 19 does not require a peripheral frame and a hanging portion. This helps ensure that the line of sight of a user viewing the display screen 11 is not interfered with. Further, it helps make the protective screen 19 inexpensive.

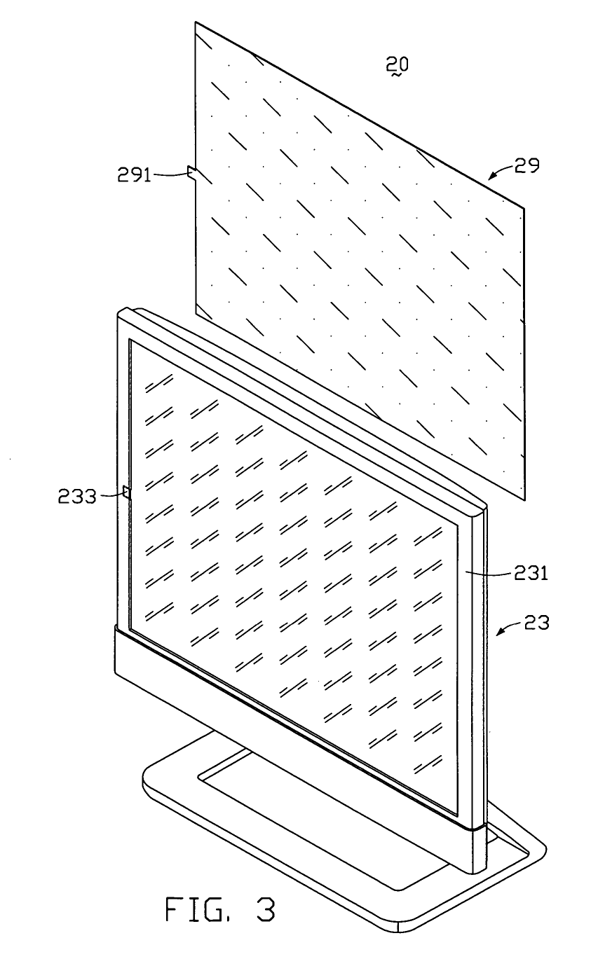

FIG. 3 is an exploded, isometric view of a display device having a protective screen according to a second embodiment of the present invention. The display device 20 has a structure similar to that of the display device 10. However, the display device 20 includes a groove 233 defined in an inner side portion (not labeled) of a front frame 231 of a housing 23. The protective screen 29 includes a protrusion 291 extending from a side portion thereof. The protrusion 291 has a size matching that of the groove 233, and is fixed in the groove 233.

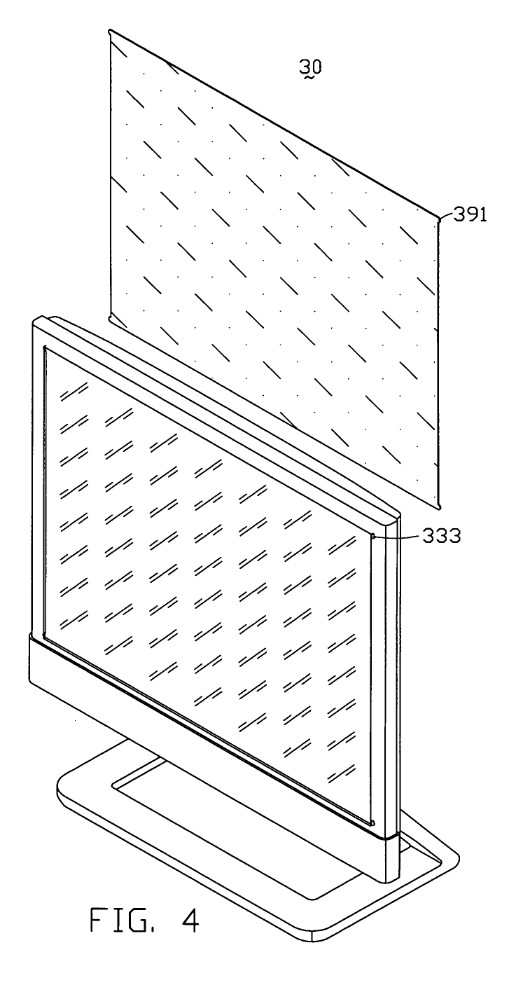

FIG. 4 is an exploded, isometric view of a display device having a protective screen according to a third embodiment of the present invention. The display device 30 has a structure similar to that of the display device 10. However, the display device 30 comprises four grooves 333 and four protrusions 391, all of which have a semicircular shape. The protrusions 391 are fixed in the grooves 333.

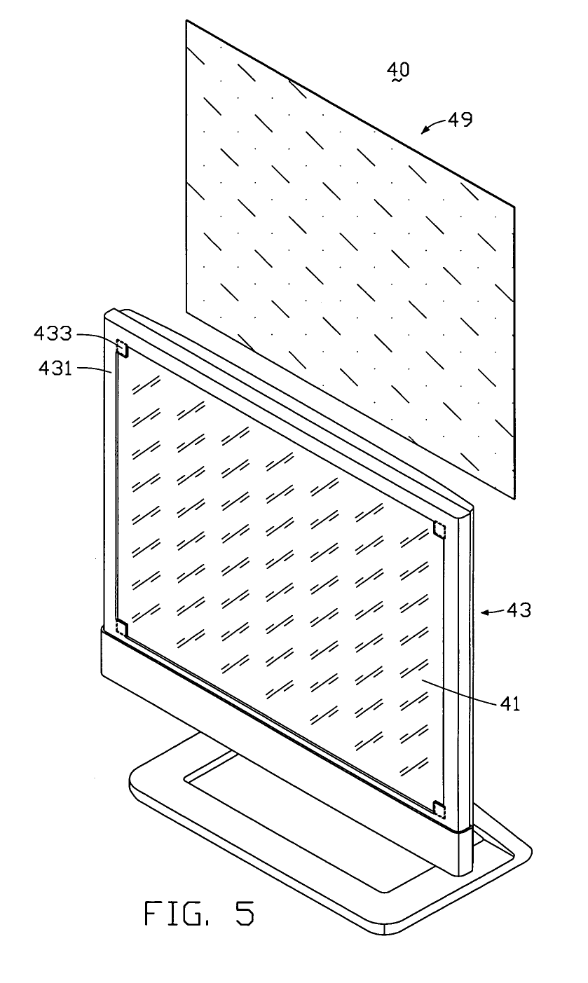

FIG. 5 is an exploded, isometric view of a display device having a protective screen according to a fourth embodiment of the present invention. The display device 40 has a structure similar to that of the display device 10. However, the display device 40 includes a display screen 41 accommodated in a housing 43, and the protective screen 49.

The housing 43 includes a front frame 431 that covers peripheral edge portions (not labeled) of the display screen 41, whereby the display screen 41 is held in the housing 43. A main central portion of the display screen 41 is not covered by the housing 43, and forms a viewing area (not labeled). The front frame 431 includes four blocks 433 disposed at four inner corners thereof respectively, the blocks 433 extending inwardly generally toward a center of the display screen 41. The protective screen 49 has a size corresponding to that of the viewing area.

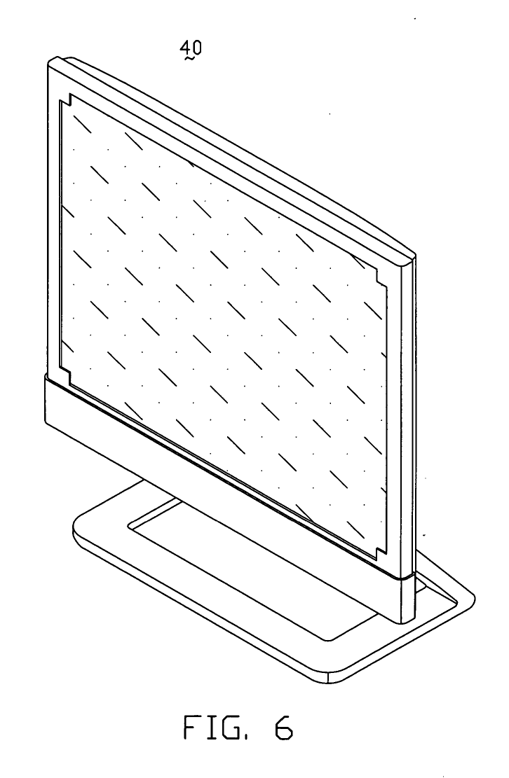

Referring to FIG. 6, in assembly, four corners of the protective screen 49 are inserted between the blocks 433 and the display screen 41. The blocks 433 cooperate with each other to fix the protective screen 49 immediately in front of the viewing area of the display screen 41.

The four blocks 433 of the front frame 431 can be considered cooperatively as forming a fixing mechanism, which conveniently provides fixing of the protective screen 49 in front of the display screen 41.

The display devices 10, 20, 30 and 40 are so-called flat display devices, and may for example be liquid crystal display devices, plasma display panels, etc. In alternative embodiments, the display devices 10, 20, 30 and 40 can for example be cathode ray tube display devices, or like apparatuses.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A display device, comprising:
a display screen;
a protective screen; and
a housing accommodating the display screen, the housing comprising a mechanism for fixing the protective screen immediately in front of the display screen.

2. The display device as claimed in claim 1, wherein the housing comprises a front frame that covers peripheral edge portions of the display screen, a main central portion of the display screen is not covered by the housing and forms a viewing area, and the protective screen has a size corresponding to that of the viewing area.

3. The display device as claimed in claim 2, wherein the mechanism comprises at least one groove provided in the front frame of the housing.

4. The display device as claimed in claim 3, wherein the mechanism comprises four grooves respectively provided in four inner corner portions of the front frame, adjacent to four corners of the viewing area respectively.

5. The display device as claimed in claim 4, wherein the protective screen comprises four protrusions extending from four corners thereof respectively, a size of the protrusions matches a size of the grooves, and the protrusions are fixed in the grooves.

6. The display device as claimed in claim 5, wherein the protrusions have a semi-circular shape.

7. The display device as claimed in claim 2, wherein the mechanism comprises a groove provided in an inner side portion of the front frame of the housing.

8. The display device as claimed in claim 7, wherein the protective screen comprises a protrusion extending from a side portion thereof, and the protrusion is fixed in the groove.

9. The display device as claimed in claim 2, wherein the mechanism comprises at least one block provided at the front frame of the housing.

10. The display device as claimed in claim 9, wherein the mechanism comprises four blocks respectively disposed at four inner corners of the front frame, and the blocks extend inwardly generally toward a center of the display screen.

11. The display device as claimed in claim 10, wherein four corners of the protective screen are fixed between the blocks and the display screen.

12. A display device, comprising:
a display screen;
a protective screen;
a housing accommodating the display screen, and
complementary interengagement structures being formed on an inner periphery of the housing and an outer periphery of the protective screen so as to retain the protective screen intimately in front of the display screen.

13. The display device as claimed in claim 12 wherein said complementary engagement structures are formed on corners of the housing and the protective screen.
